(19) United States
(12) Patent Application Publication
(10) Pub. No.: US 2015/0268788 A1
(43) Pub. Date: Sep. 24, 2015

(54) MULTIPLE SYSTEM INTEROPERABLE INTERACTIVE GRAPHICAL USER INTERFACE WITH UPGRADABLE, EXCHANABLE, AND USER REMOVABLE CENTRAL PROCESSING UNIT CARD

(71) Applicant: Murat Erdogan, Greeley, CO (US)

(72) Inventor: Murat Erdogan, Greeley, CO (US)

(73) Assignee: LUCAN TECHNOLOGIES, INC., Greeley, CO (US)

(21) Appl. No.: 14/220,571

(22) Filed: Mar. 20, 2014

(51) Int. Cl. G06F 3/041; G06F 3/0488; G06F 3/0484; G06F 1/16; H05K 7/14

(52) U.S. Cl. CPC G06F 3/0416; G06F 1/1684; H05K 7/1422; G06F 3/0484; G06F 3/04886

(57) ABSTRACT

A computer implemented method in conjunction with a touch screen companion computer device which provides an interactive graphical user interface interoperable with each of a plurality of computer systems and accommodates an upgradable, exchangeable, and user removable Central Processing Unit (CPU) Card that includes all major components such as the microprocessor, RAM, Flash Memory, all critical chips, SD card and SIMM Card Connectors and other critical components, a touch screen computer enclosure device which includes all major external connectors and hardware such as power connector, battery, Wireless radio Antennas, USB connectors, HDMI, the LCD and other common features, and one or more programs which detect wired or wireless connections, connected device types, active running applications on the remote connected plurality of computer devices, and configuring the touch screen companion device based on user preferences, predefined configurations, or configuration files provided by computer applications being used.

### I. BACKGROUND OF THE INVENTION

Conventional computer devices include one or more user input devices which allow the user to interact with a corresponding one or more graphical user interfaces generated by corresponding application programs displayed on the monitor of a computer device. For example, conventional personal computers may provide a mouse and associated pointer along with a keyboard for interaction with the graphical user interface discretely displayed on a monitor of the computer. This hardware configuration requires the user to interact with the keyboard discrete from the mouse and again the mouse operates to position a pointer on a discrete display surface. It can be time consuming for the user to move between several discrete input surfaces to interact with the graphical user interface generated by an application program.

Conventional tablet and notebook computer devices may also include critical components such as the microprocessor, RAM, Flash Memory, all critical chips, Flash memory, HDD, SD card and SIMM Card Connectors and other critical components as well as external connectors and hardware such as power connector, battery, wireless radio antennas, USB connectors, HDMI, the LCD and other common features. Currently these features are soldered on one or more PCBs and custom designed for each specific system. In most cases the units are assembled such that end users cannot upgrade any components without damaging the unit. In some cases solder and glue is used to permanently affix the components in the enclosures. This conventional design practice does not allow for any upgrades and the repairs are costly and time consuming. In most cases the devices are recycled prematurely, ending up as e-waste within a few short years.

The instant invention provides a re-usable, upgradable, and exchangeable companion computer device having upgradable, exchangeable, and user removable CPU card and a computer-readable medium having computer-executable instructions which operate to address each of the above identified problems associated with conventional user interface input events and conventional computer devices.

### II. SUMMARY OF THE INVENTION

A broad object of the invention can be to provide a companion computer device which provides an interactive graphical user interface interoperable with each of a plurality of computer systems.

Another broad object of the invention can be to provide a companion display surface on which a companion graphical user interface can be displayed which allows the user interaction with any one of a variety of application programs run on any one of plurality of computer systems without having to utilize the conventional input devices associated with any one of the plurality of computer systems.

Another broad object of the invention can be to provide a companion application program executable to identify and connect to any of a plurality of computer systems or monitors, or in the absence of any other hardware to operate in a tablet mode.

Another broad object of the invention can be to provide a companion application program executable to select between a plurality of user configurations each of which concurrently display on a companion display surface one or more graphical input devices for user interaction with the application program running in a first computer or by the companion device, or both, and further display a portion or all of the application program interface for interactive touch by the user on the companion display surface.

Another broad object of the invention can be to provide an easy way to service, or upgrade the system hence increasing the total use life of the system and reducing e-waste.

Another broad object of the invention can be to provide an easily removable CPU Card that can hold critical user information, system configuration, personal and work data to increase security.

Another broad object of the invention can be to provide a small removable CPU Card that can hold all critical data as well as user configuration and settings such as desktop layout or theme etc. and can be plugged into plurality of form factor systems such as a 7″ tablet, a 10″ tablet, a 14″ tablet, a touch capable Monitor or a companion computer device and provide the same experience across all platforms, hence simplifying the management of multiple devices.

Another broad object of the invention can be to simplify system design by separating the common PC components such as the enclosure, the touch capable LCD, and the connectors and the critical components such as the CPU, Memory, storage and other components.

Another broad object of the invention can be to reduce overall system cost by allowing customization, configuration and optimization of the enclosures and core CPU boards independently.

Another broad object of the invention can be to simplify manufacturing, assembly, serviceability and reparability of the systems.

Naturally, further objects of the invention are disclosed throughout other areas of the specification, drawings, photographs, and claims.

### III. BRIEF DESCRIPTION OF THE DRAWINGS

FIG. 1 is an illustration of a particular embodiment of the inventive companion computer device operably coupled with a first computer to allow a user to input touch events to execute a function of an application program contained in a memory of either the first computer device or the companion device.

FIG. 2 is a block diagram of an illustrative computer means, network means and computer-readable medium which provides computer-executable instructions to provide a particular embodiment of the companion computer device and companion application program interoperable with a first computer, a monitor, or operate discretely in a tablet mode.

FIG. 3 is a perspective view of a particular embodiment of the inventive companion computer device.

FIG. 4 is a top view of a particular embodiment of the inventive companion computer device.

FIG. 5 is a bottom view of a particular embodiment of the inventive companion computer device.

FIG. 6 is a front view of a particular embodiment of the inventive companion computer device.

FIG. 7 is a back view of a particular embodiment of the inventive companion computer device.

FIG. 8 is a first end view of a particular embodiment of the inventive companion computer device.

FIG. 9 is a second end view of a particular embodiment of the inventive companion computer device.

FIG. 10 is a block flow diagram which shows a particular embodiment of the companion application program executable to implement the various functionalities of the companion computer device.

FIG. 11 block flow diagram which shows a particular embodiment of a connection module of the companion application program and a process to connect the companion computer device to a first computer and further shows a particular embodiment of a mode module and a process to select a mode of operation for the companion computer device.

FIG. 12 is a block flow diagram which shows a particular embodiment of a connection module routine to connect to a first computer through a local area network to the companion computer device.

FIG. 13 is a block flow diagram which shows a particular embodiment of a connection module routine to connect to a first computer by WiFi to the companion computer device.

FIG. 14 is a block flow diagram which shows a particular embodiment of a connection module routine to connect to a first computer by 3G/4G to the companion computer.

FIG. 15 is a block flow diagram which shows a particular embodiment of a connection module routine to connect to a first computer by USB and Bluetooth to the companion computer.

FIG. 16 is block flow diagram which shows a particular embodiment of a mode module routine to select the mode of operation for the companion computer device.

FIG. 17 is a block flow diagram which shows a particular embodiment of a mode module routine for implementing the personal computer companion mode of the companion computer device.

FIG. 18 is a block flow diagram which shows a particular embodiment of a mode module routine for implementing the personal computer mode of the companion computer device.

FIG. 19 is a block flow diagram which shows a particular embodiment of a mode module routine for implementing a tablet mode of the companion computer device.

FIG. 20 is a block flow diagram which shows a particular embodiment of a configuration module routine for generating a system configuration including a first computer and a particular embodiment of the companion computer device.

FIG. 21 is a block flow diagram which shows a particular embodiment of a configuration module routine for generating a user configuration in the context of a first computer and a particular embodiment of the companion computer device.

FIG. 22 is a block flow diagram which shows a particular embodiment of a configuration module routine for generating one of a plurality of user configuration in a personal computer companion mode.

FIG. 23 is a block diagram which illustrates various user configuration implemented in the personal computer companion mode.

FIG. 24 is an illustration of a default user configuration (also referred to as “a first user configuration”) in the personal computer companion mode.

FIG. 25 is an illustration of a second user configuration in the personal computer companion mode.

FIG. 26 is an illustration of a third user configuration in the personal computer companion mode.

FIG. 27 is an illustration of a fourth user configuration in the personal computer companion mode.

FIG. 28 is an illustration of a fifth user configuration in the personal computer companion mode.

FIG. 29 is a block flow diagram which shows a particular embodiment of a layout configuration module routine for setting a system layout in the context of a first computer embodiment of the companion computer device.

FIG. 30 is a sub list of possible layout configuration that can be used by user or the system.

FIG. 31 is an example layout depicting the screen of the companion computer device divided in to five different blocks and assignment of five unique applications running concurrently.

FIG. 32 is an exploded view of the removable CPU card and its major components.

FIG. 33 is a block diagram of the companion computer device as a whole, representing the enclosure (214) and the removable CPU card (215) and all of its subcomponents, electrical connections, network means, storage means, display means, power means, and all the necessary means to for the device to interoperate with a first computer, a monitor, or operate discretely in a tablet mode.

### IV. DETAILED DESCRIPTION OF THE INVENTION

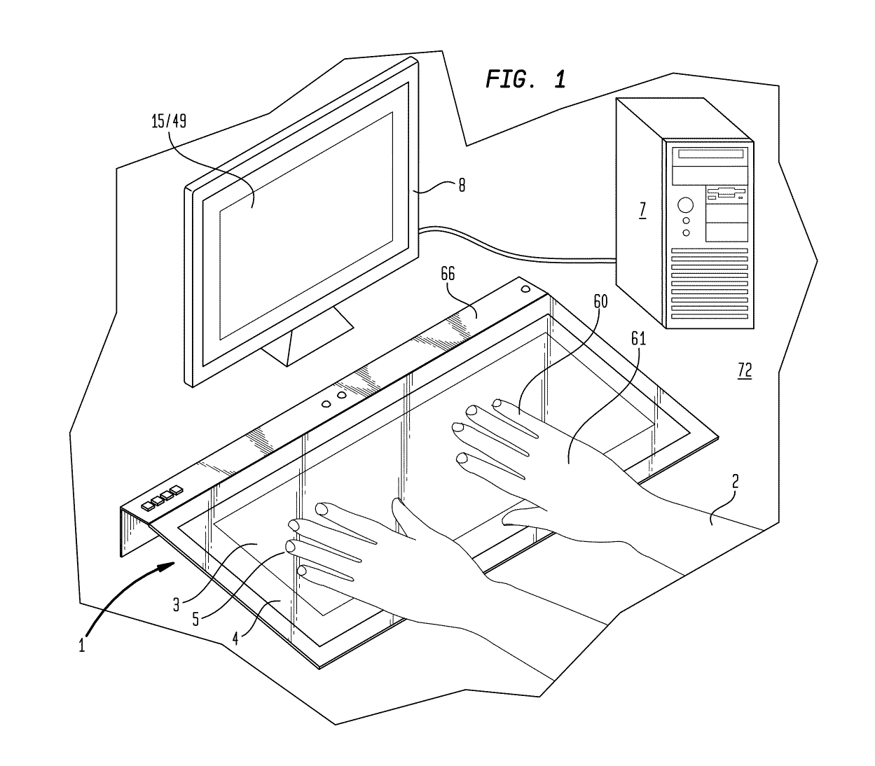

Now referring primarily to FIG. 1, which generally illustrates a companion computer device (1) which by user (2) interaction with a companion graphical user interface (3) displayed on a companion display surface (4) allows click events (5) by user (2) touch for selective activation of the various routines and functions of a companion application program (6) which allows interconnection and interoperability of the companion computer device (1) with various forms of a first computer (7), monitors (8), or to operate discrete from any other computer (7) or monitor (8).

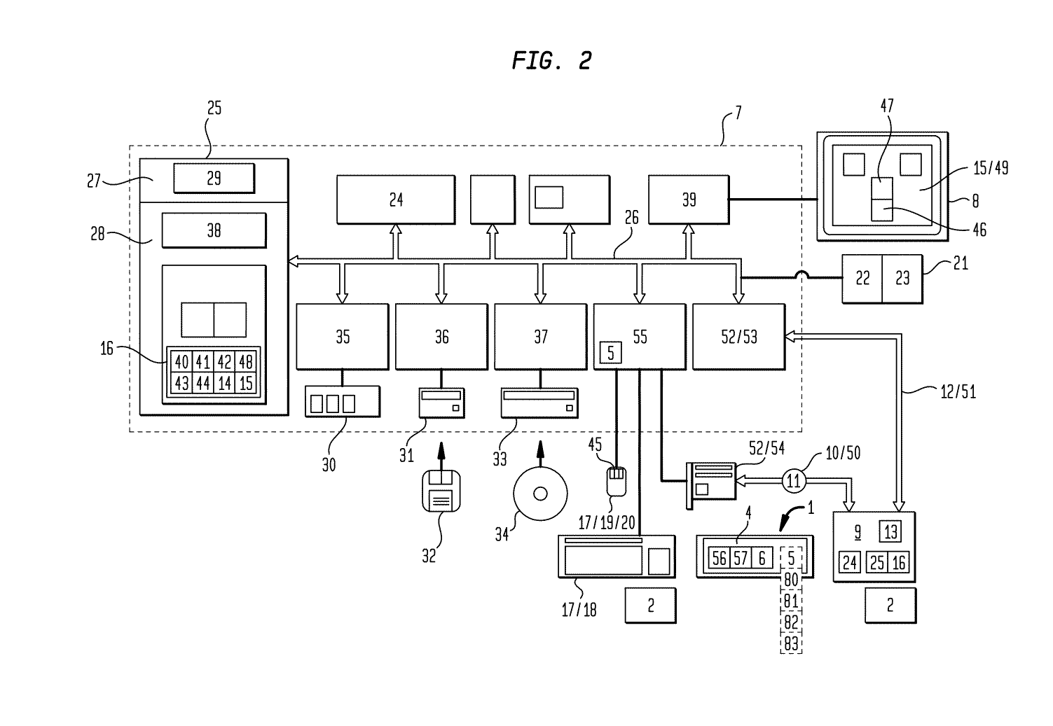

Now referring primarily to FIG. 2, which generally illustrates computer means, certain network means, and computer readable media which can be utilized to practice embodiments of the invention. It is not intended that embodiments of the invention be practiced in only wide area computing environments or only in local computing environments, but rather the invention can be practiced in local computing environments or in distributed computing environments where functions or tasks are performed by remote processing devices that are linked through a communications network. In a distributed computing environment, program modules may be located in both a local or in a remote memory storage device(s) or device elements.

Also while a preferred embodiment of the invention is described in the general context of computer-executable instructions such as an application program and program modules which utilize routines, programs, objects, components, data structures, or the like, to perform particular functions or tasks or implement particular abstract data types, or the like, being executed by the computer means and network means, it is not intended that any embodiments of the invention be limited to a particular set of computer-executable instructions or protocols.

Now referring to primarily to FIGS. 1 and 2, a first computer device (7) can be configured to connect with one or more second computer devices (9) through a wide area network (10) (“WAN”), such as the Internet (11), or one or more local area networks (12) (“LAN”) to transfer data (13). The first computer device (7) can, as to particular embodiments, take the form of a limited-capability computer designed specifically for navigation on the World Wide Web of the Internet (11). Alternatively, the first computer device (7) might be set-top boxes, intelligent televisions connected to receive data through an entertainment medium such as a cable television network or a digital satellite broadcast, hand-held devices such as smart phones, slate or pad computers, personal digital assistants or camera/cell phone, or multiprocessor systems, microprocessor-based or programmable consumer electronics, network personal computers, minicomputers, mainframe computers, or the like.

Again referring primarily to FIG. 2, the first computer device (7) can further include an Internet browser (14) such as Microsoft's INTERNET EXPLORER, GOOGLE CHROME, MOZILLA, FIREFOX, or the like, which functions to download and render multimedia content that is formatted in “hypertext markup language” (HTML). In this environment, the second computer device (9) might be programmed to implement the most significant portions of a user interface (15). As to these embodiments, the application program (16) which implements the user interface (15) can be resident in the second computer device (9) and the first computer device (7) can use the browser (14) to simply display downloaded content and to relay user inputs back to the second computer device (9). The second computer device (9) would respond by formatting new screen displays as part of the user interface (15) and downloading them for display on one or more of first computer devices (7).

In other embodiments, the second computer device (9) can be used primarily as sources of data (13), with primary responsibility for implementing a user interface (15) placed upon each of the first computer devices (7). As to these embodiments, each of the first computer devices (7) can run the application program (16) implementing the user interface (15) on the first computer (7) and to retrieve data (13) from the second computer device (9).

The user (2) can enter commands and information into the first computer device (7) through input devices (17) such as a keyboard (18) or a pointing device (19) such as a mouse (20); however, any method or device that converts user action into commands and information can be utilized including, but not limited to: a microphone, joystick, game pad, touch screen, or the like. The monitor (8) or other type of display device can also be connected to the bus (26) via a video interface (39), such as a video adapter, or the like. The first computer device (7) and the second computer device (9) can further include peripheral output devices (21) such as speakers (22) and printers (23); although the peripheral output devices (21) are not so limited.

Again referring primarily to FIG. 2, as an illustrative example, the first computer device (7) can include a processing unit (24), one or more memory elements (25), and a bus (26) (which operably couples components of the first computer (7), including without limitation the memory elements (25)) to the processing unit (24). The processing unit (24) can comprise one central-processing unit (CPU), or a plurality of processing units which operate in parallel to process digital information. The bus (26) may be any of several types of bus configurations including a memory bus or memory controller, a peripheral bus, and a local bus using any of a variety of bus architectures. The memory element (25) can without limitation be a read only memory (ROM) (27) or a random access memory (RAM) (28), or both. A basic input/output system (BIOS) (29), containing routines that assist transfer of data (13) between the components of the first computer device (7), such as during start-up, can be stored in ROM (28). The first computer device (7) can further include a hard disk drive (30) for reading from and writing to a hard disk (not shown), a magnetic disk drive (31) for reading from or writing to a removable magnetic disk (32), and an optical disk drive (33) for reading from or writing to a removable optical disk (34) such as a CD ROM or other optical media. The hard disk drive (30), magnetic disk drive (31), and optical disk drive (33) can be connected to the bus (26) by a hard disk drive interface (35), a magnetic disk drive interface (36), and an optical disk drive interface (37), respectively. The drives and their associated computer-readable media provide nonvolatile storage of computer-readable instructions, data structures, program modules and other data for the first computer device (7). It can be appreciated by those skilled in the art that any type of computer-readable media that can store data that is accessible by a computer, such as magnetic cassettes, flash memory cards, digital video disks, Bernoulli cartridges, random access memories (RAMs), read only memories (ROMs), and the like, may be used in a variety of operating environments. A number of program modules may be stored on the hard disk drive (30), magnetic disk (32), optical disk (33), ROM (27), or RAM (28), including an operating system (38), one or a plurality of application programs (16), as illustrative examples: a word processing application program(s) (40) (for example WORD), an e-mail application (41) (such as OUTLOOK), a presentation application (42) (such as POWERPOINT), graphical web browser application (43) (such as EXPLORER), a portable document format application (44) (such as ACROBAT) which implement one or more user corresponding user interfaces (15).

A “click event (5)” occurs when the user (2) operates an application function through the use of a command which for example can include pressing or releasing a left mouse button (45) while a pointer (46) is located over a control icon (47) (or other interactive field which activates a function) displayed in a user interface (15). However, it is not intended that a “click event (5)” be so limited, rather, a “click event (5)” is intend to broadly encompass a command by the user (2) through which a function of an application program (16) (or other program, application, module or the like) including without limitation a graphical user interface application (48) which in part implements a graphic user interface (49), whether through selection of one or a plurality of control icon(s) (47) or fields, or by user touch command, voice command, keyboard stroke, mouse button, or otherwise.

Again referring to FIG. 2, the first computer device (7) may operate in a networked environment using one or more logical connections (50) (51) to connect to one or more second computer devices (9). These logical connections (50) (51) are achieved by one or more communication devices (52) coupled to or a part of the first computer device (7). The logical connections (50) (51) depicted in FIG. 2 can include a LAN (12) or a WAN (10). Such networking environments are commonplace in offices, enterprise-wide computer networks, intranets, wireless networks, global satellite networks, cellular phone networks and the Internet (11). The one or more second computer devices (9) can be another computer, a server, a router, a network personal computer, a client, a peer device or other common network node, and can include in part or in whole all of the hardware elements and application programs above-described relative to the first computer device (7), even though only a second computer processor (24) and a second computer memory (25) containing one or more application programs (16) are shown.

When used in a LAN-networking environment, the first computer device (7) can be connected to the local network (12) through a local network interface (53), which is one type of communications device (52). When used in a WAN-networking environment, the first computer device (7) typically includes a modem (54), another type of communications device (52), or any other type of communications device for establishing communications over the wide area network (10), such as the Internet (11). The modem (54), which may be internal or external, is connected to the bus (26) via a serial port interface (55). In a networked environment, application programs (16) depicted relative to the first computer device (7), or portions thereof, may be as to certain embodiments of the invention be stored in the one or more second computer devices (9). It is appreciated that the network connections shown are exemplary and other means of and communications devices for establishing a communications link between one or more first computer devices (7) and one or more second computer devices (9) can be used.

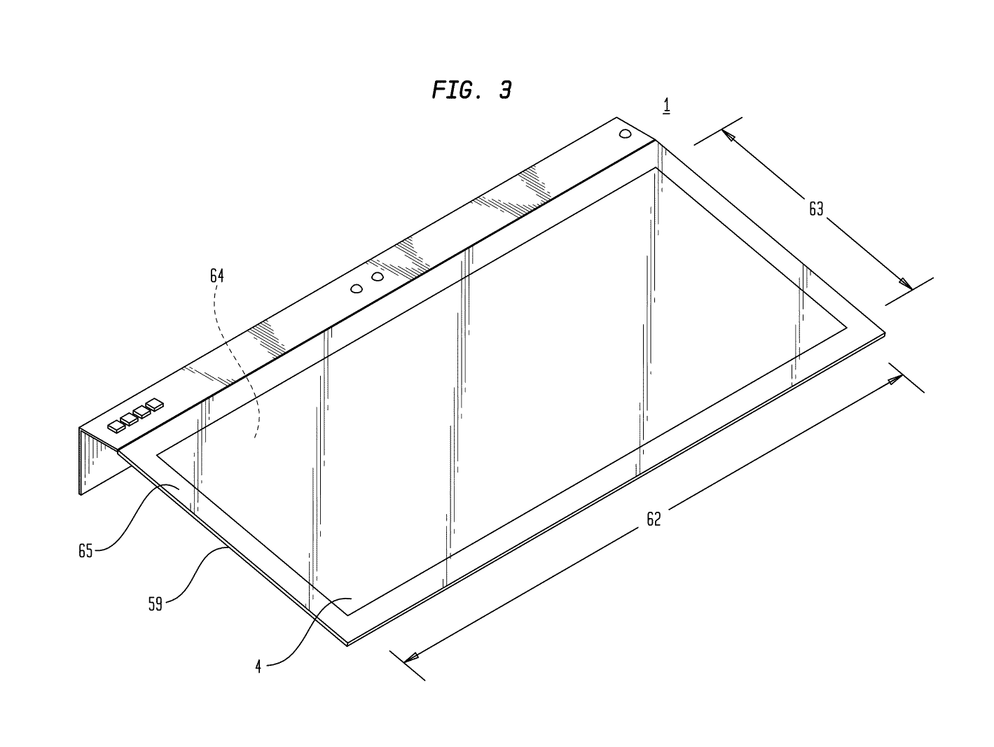

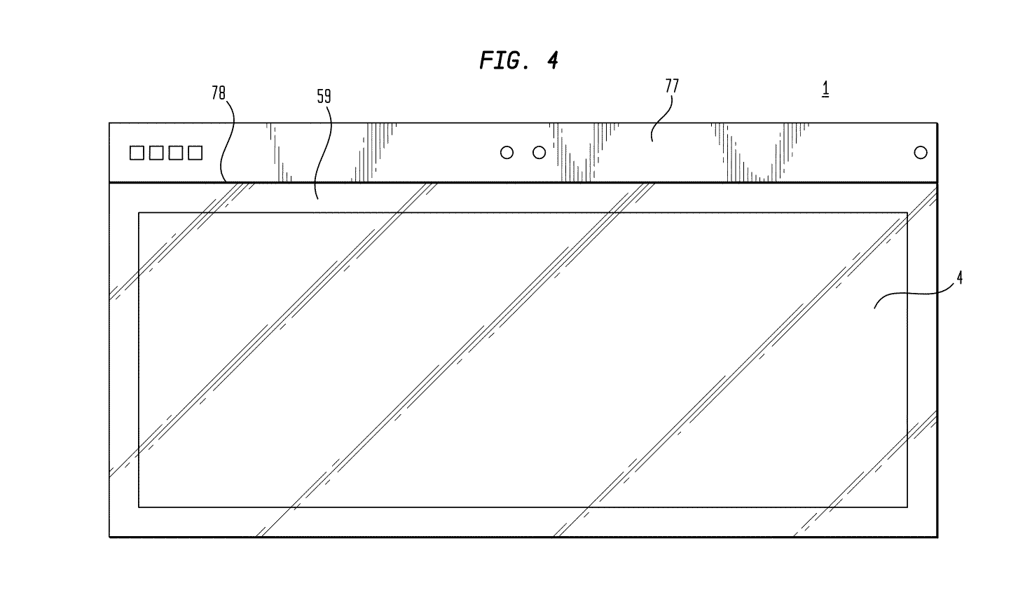

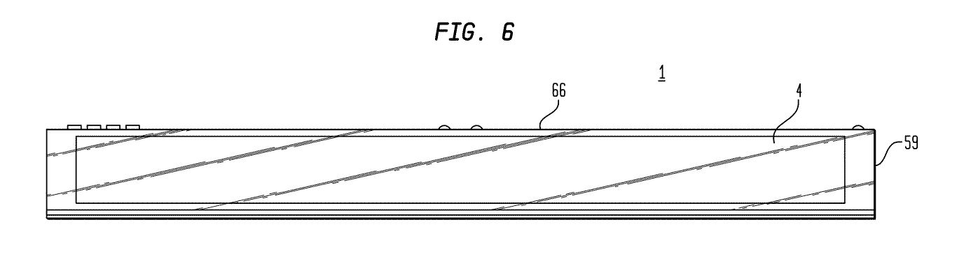

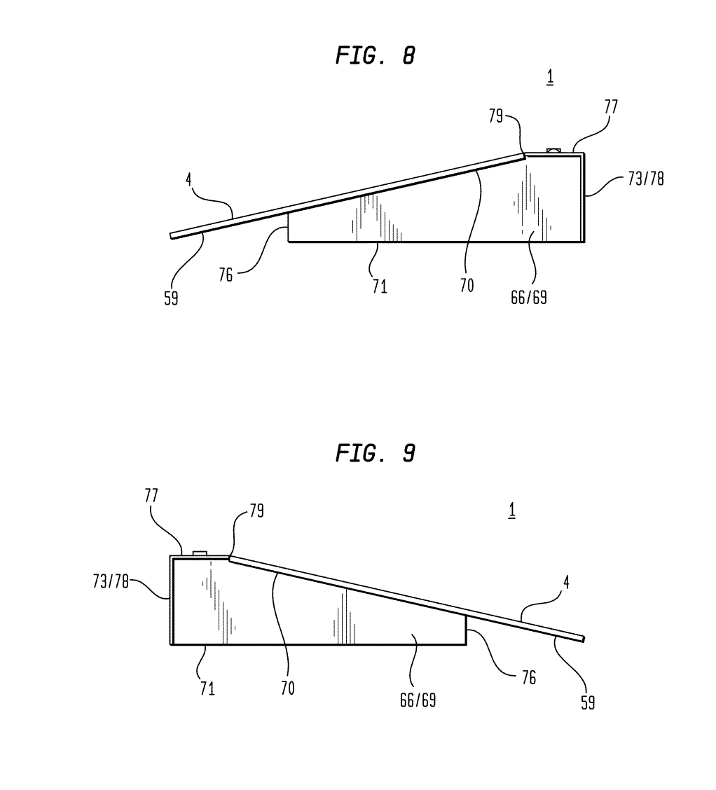

Now referring primarily to FIGS. 1 through 9, embodiments of the invention can further include a companion computer device (1) which can include all of the computer means, network means, and application programs above-described relative to the first computer device (7) or the second computer device (9), even though only a companion device processor (56) and a companion device memory (57) containing the companion application program (6) is shown. The companion computer device (1) provides a companion graphical display surface (4) coupled to a companion display surface housing (59). As to preferred embodiments, the companion graphical display surface (4) can be generally take the form of a flat elongated rectangle having dimensional relations sufficient for interactive touch with the digits (60) of one or both hands (61) of a user (2) (as shown in the illustrative example of FIG. 1). As to particular embodiments, the companion display surface (4) can provide a flat surface having a length (62) in the range of about 10 inches and about 20 inches and a width (63) in the range of about 3 inches to about 8 inches (as shown in the example of FIG. 3). As to a preferred embodiment, the companion display surface (4) can have a length (62) of about 14 inches and a width (63) of about 6 inches.

As to particular embodiments, the companion display surface housing (59) can define a display enclosed space (64) of sufficient volume to contain the computer means, as above described. In a preferred embodiment, the display surface housing (59) encloses an integrated circuit board which supports the companion device processor (56) operably coupled to the companion device memory (57) capable of containing the companion application program (58) without the moving parts and interface associated with a hard disk drive (30). As to particular embodiments, the companion display surface housing (59) can have an external surface (65) configured similar to a tablet or slate computer and house the computer means.

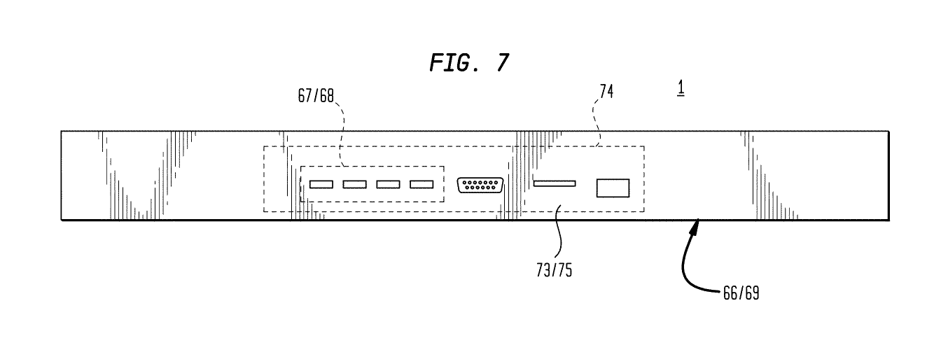

As to other embodiments, the companion computer device (1) can further include a base (66) which supports or adjustably supports the companion display surface (4) at a location for interactive engagement by the digits (60) of one or both of the hands (61) of user (2) (as shown in the example of FIGS. 3-9). As to certain embodiments the base (66) affords support for the companion display surface (4) having the companion display surface housing (59) which contains the computer means, as above described. As to other embodiments the companion display surface (4) and companion display surface housing (59) can couple or removably couple to the base (66) and the base (66) can further define a base enclosed space (77) of sufficient volume to contain the computer means as described above and can as to certain embodiments include a companion hard drive (67) and a companion hard drive interface (68) or other drives and interfaces (as shown in the example of FIG. 7).

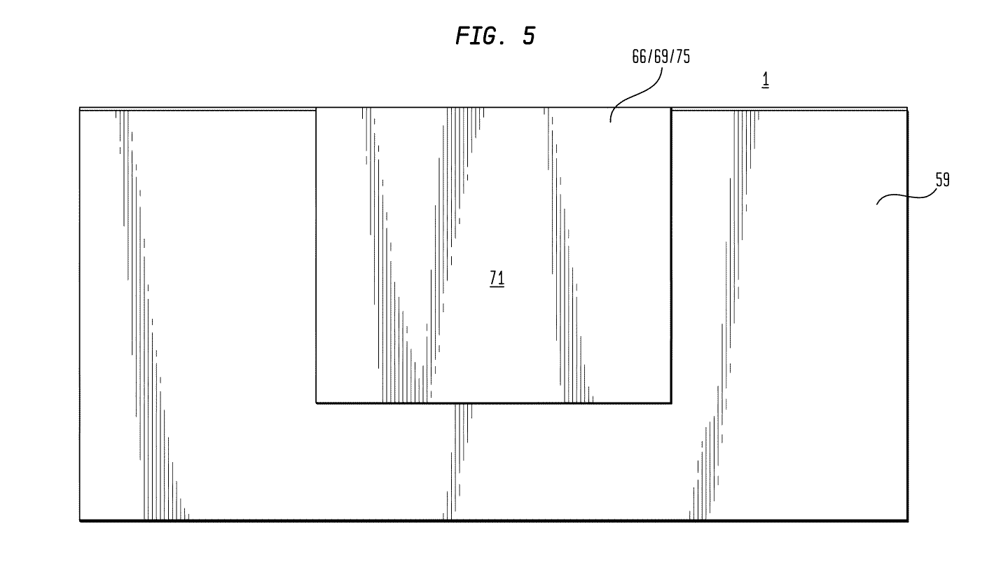

Now referring primarily to FIGS. 5, 8, and 9, which show an illustrative example of a base (66) including a base housing (69) having a substantially flat top face (70) disposed in inclined or inclinable relation to a substantially flat bottom face (71) configured to engage a support surface (72), a back face (73) which can provide apertures through which one or more connectors or ports communicate between a base enclosed space (74) and a base external surface (75) of the base (66), and a front face (76). The top face (70) can further provide a top face panel (77) having a first top face panel edge (78) configured for mated engagement along the entire length of the companion display surface housing (59) and a second top face panel edge (79) which joins a back face panel (78) that can extend downwardly to engage the support surface (72). This illustrative example is not intended to be limiting with respect to the structural configurations of the base housing (69) but rather is intended to provide a person of ordinary skill in art a description sufficient to make and use a numerous and wide variety of base configurations useful in supporting the companion display surface (4) or contain the computer means, or both.

Again referring primarily to FIG. 2, the companion computer device (1) can include a companion device memory (57) which contains a companion application program (16) including code executable to implement various routines, functions, and displays associated with the companion computer device (1).

Now referring to FIG. 33, which is a block diagram of the companion computer device (1) as a whole, representing the enclosure chassis (214) and the removable CPU card (215) and all of its subcomponents, electrical connections, network means, storage means, display means, power means, and all the necessary means to for the device to interoperate with a first computer, a monitor, or operate discretely in a tablet mode. The removable CPU card (215) includes a Central Processing Unit (218) with GPU and DSP, one or more memory elements (220), one or more storage elements (221), one or more network or wireless communication elements (223), one or more USB elements (224). The removable CPU card can also have one or more SDCARD connectors or slots (219), SIMM Card connectors or slots (222), Audio elements (225), Camera elements (226), GPS elements (227). The removable CPU card can have some means such as a connector (217) or gold fingers or other means to connect to the enclosure connector within the companion computer device (1). The enclosure Chassis (214) can include the power delivery elements (228) containing input for Power (228), battery charger elements (230), a physical battery (231), and power converter elements (231). The enclosure Chassis (214) can include one or more buttons (232), audio elements (233), one or more physical antennas (234), one or more USB ports (235), one or more camera elements (236), one or more video or HDMI ports/connectors (237), one or more indicator LEDs (238), and other critical features like Accelerometer (239), Gyroscope (240).

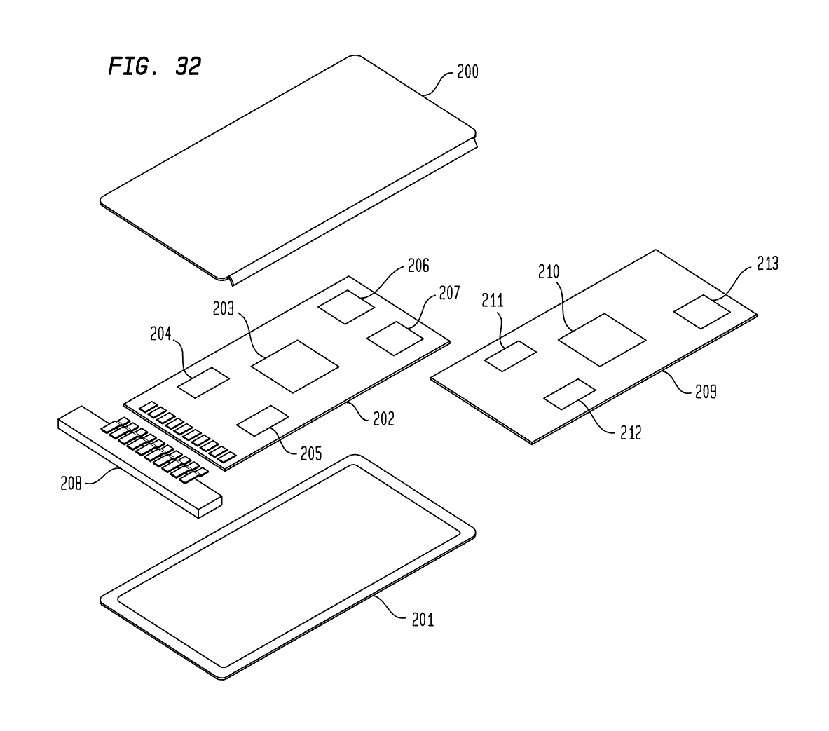

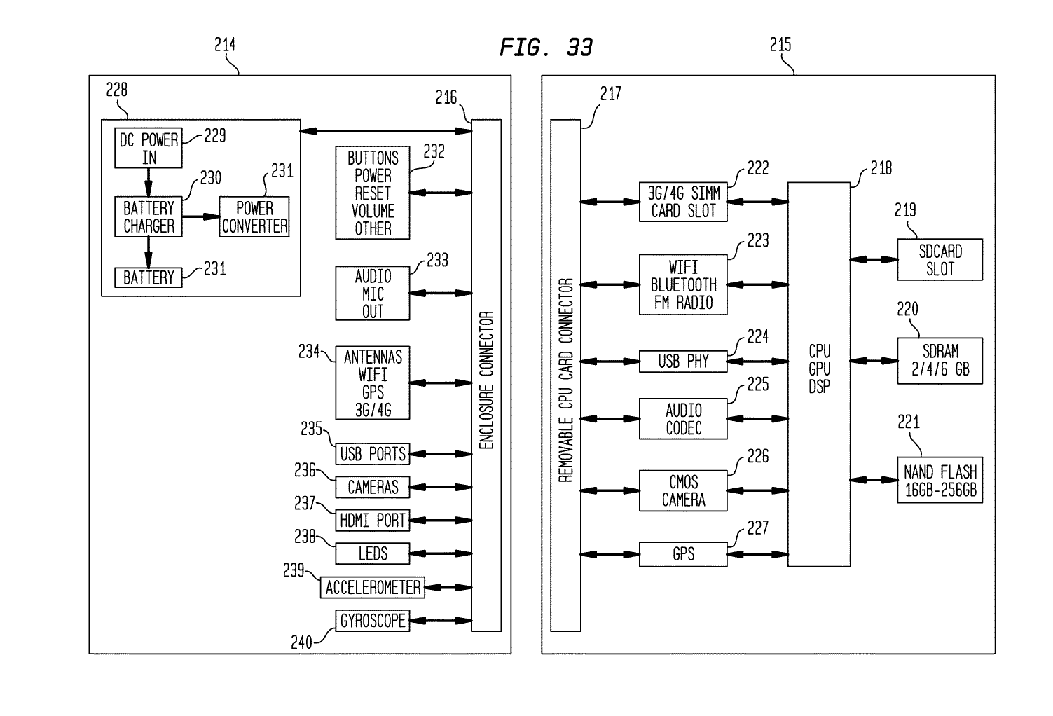

Now referring to FIG. 32, which is an exploded view of the removable CPU card and its major components, the critical components such as top enclosure cover (200), bottom enclosure cover (201), main PCBA (202,209), and an edge connector (208). The top side of the PCBA (202) can contain components such as the CPU (203), SDRAM (204,205), SDCARD connector (206), and SIMM Card connector (207). The bottom side view of the PCBA (202) can contain components such as the SDRAM (211, 212), NAND Flash (210), and network/wireless/communication elements (213).

The removable CPU Card also can have an edge connector (208) for connecting signals between the CPU card and the companion computer device (1) and its circuitry. On insertion of the CPU Card in FIG. 32 into the companion computer device (1), connector (208) is detachably and electrically coupled with a corresponding connector on a system PCB within the companion computer device (1).

When the companion computer device (1) is powered up, the system PCB power delivery elements supply power to the removable CPU Card through Enclosure Connector (216) and CPU Card Connector (217) and the CPU (218) in Removable CPU Card configures and control all system resources, elements, and functions of the companion computer device (1). The CPU can perform various operating system functions such as program execution, user input management, display of necessary information, setting up or configuring settings, profiles or configurations, monitoring status.

Although the electrical system has been illustrated in one form as the companion computer device (1), the system can be a tablet or a monitor having appropriate features such as have been described previously.

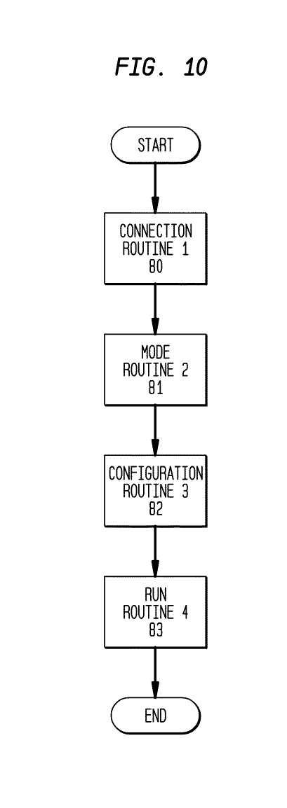

Now referring primarily to FIG. 10, the companion application program (16) can include one or more of four basic modules: a connection module (80), a mode module (81), a configuration module (82), and a run module (83).

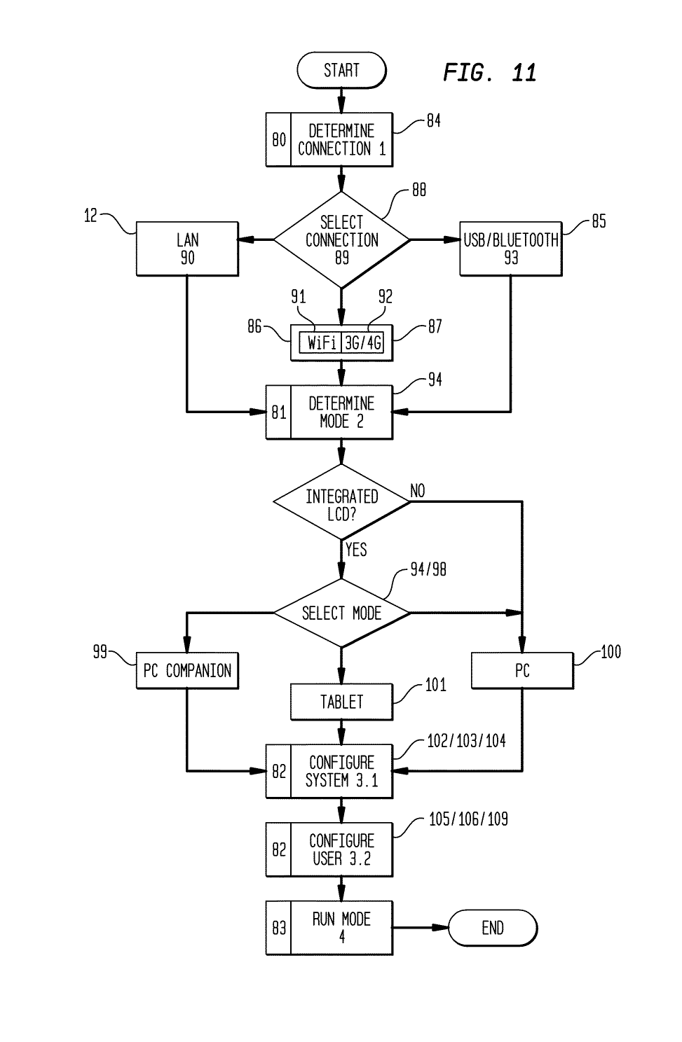

Now referring primarily to FIG. 11, the connection module (80) functions in a first connection step (84) to determine which connections are available to interconnect the companion computer device (1) with the first computer device (7) or second computer device (9) such as LAN (12), universal serial bus (“USB”)/Bluetooth (85), wireless area network (“WiFi”) (86), 3G mobile telephone/4G mobile telephone ( )“3G/4G”) (87), or the like.

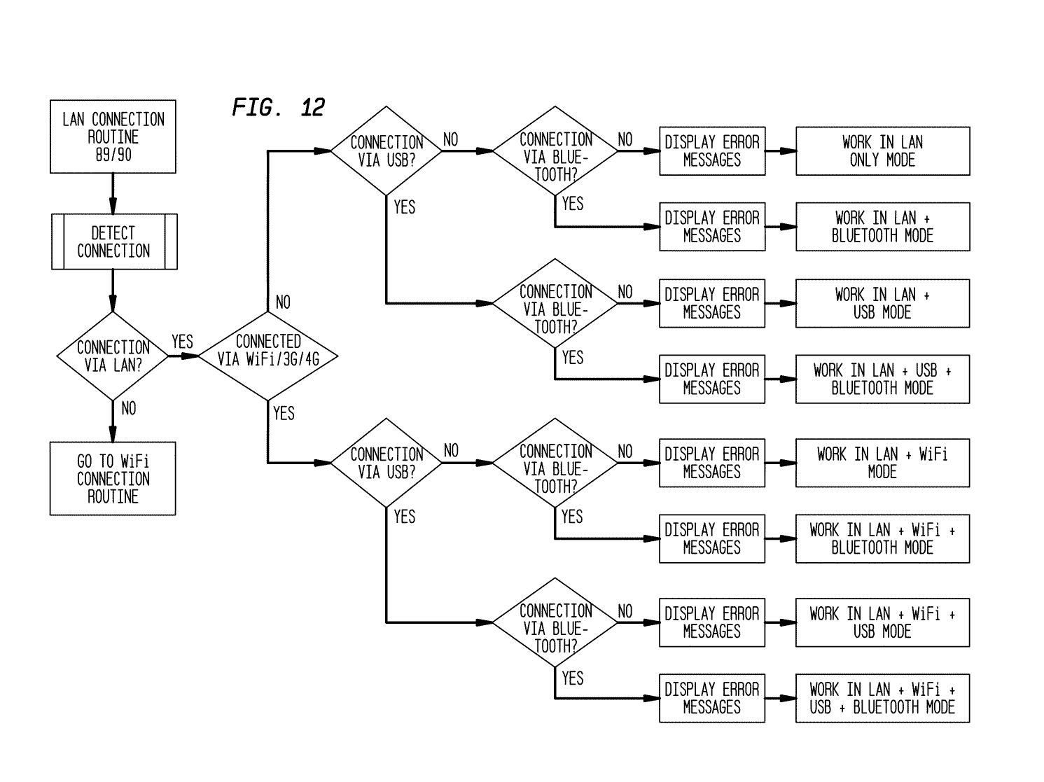

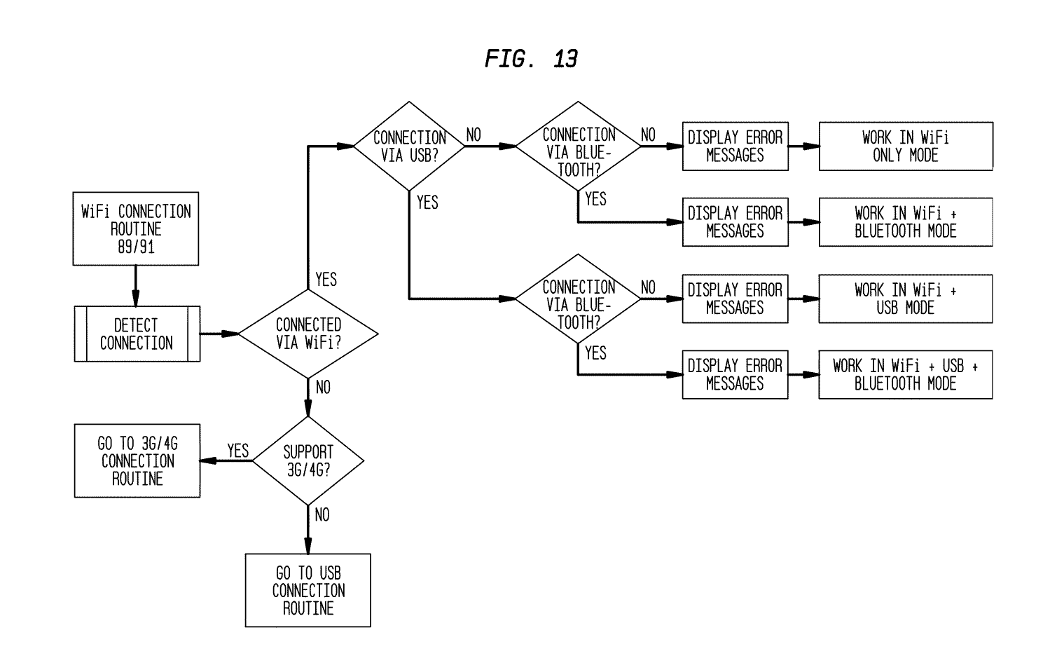

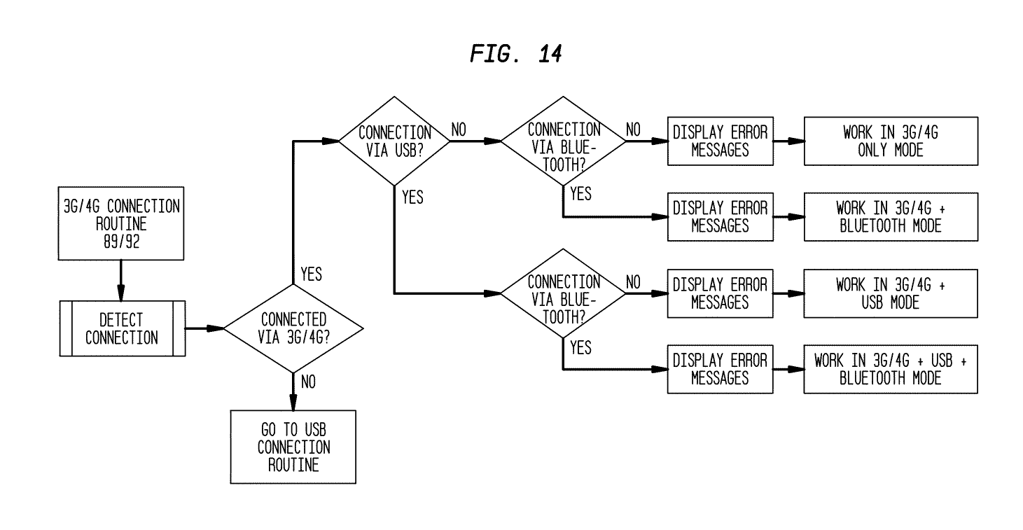

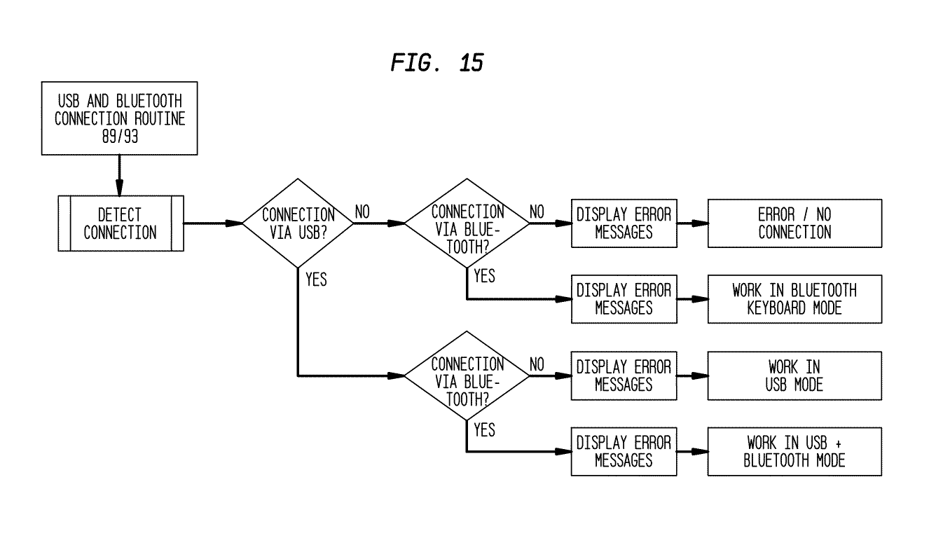

In a second connection step (88) either by independent operation of the connection module (80) or by user (2) interaction in a companion graphical user interface (3) a connection routine (89) can be selected based on the connections detected including a LAN connection routine (90) (as shown in the example of FIGS. 11 and 12), a WiFi connection routine (91) (as shown in the example of FIGS. 11 and 13), a 3G/4G connection routine (92) (as shown in the example of FIGS. 11 and 14), or a USB/Bluetooth connection routine (93) (as shown in the example of FIGS. 11 and 15). However, these examples are not intended to be exclusive of other connection routines (89) that could be utilized as technology develops or with respect to the decision path implemented by operation of the connection module (81) in selection of one or more connections with the first computer device (7) or the second computer device (9).

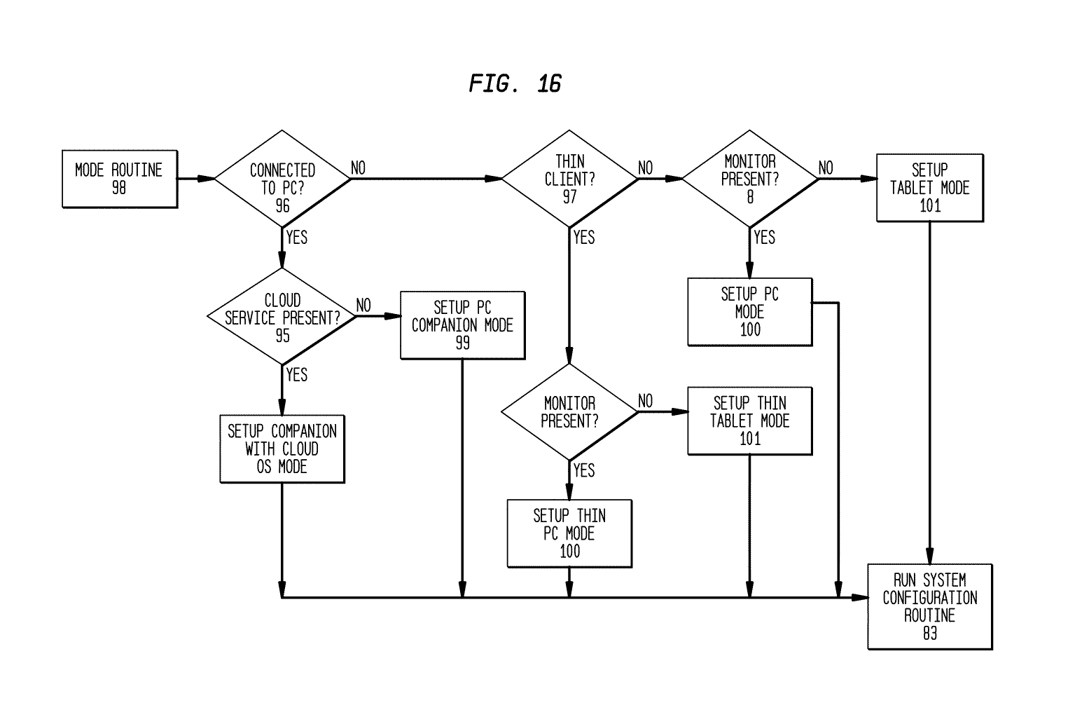

Again referring to FIGS. 10 and 11, the companion application program (16) can further include a mode module (81) which functions in a first mode step (94) to determine which hardware configurations are available for operation of the companion computer device (7). Now referring primarily to FIG. 16, the mode module (81) operates to determine if the companion computer device (1) can be interconnected with a first computer (7) in a form including one or more of: a cloud computer (95) in which computer means and computer readable media are delivered over a network typically the Internet (11), a personal computer (96) equipped with a processor (24) and containing in a memory (25) one or more application programs (39) (as shown for example in FIG. 2 and above described), a thin personal computer (97) which communicates with a second computer (9) (server computer) which serves program applications (16) (as shown in the example of FIG. 2), a monitor (8) operably discrete from any form of first computer (7) or second computer (9), or if no interconnection can be made with other hardware.

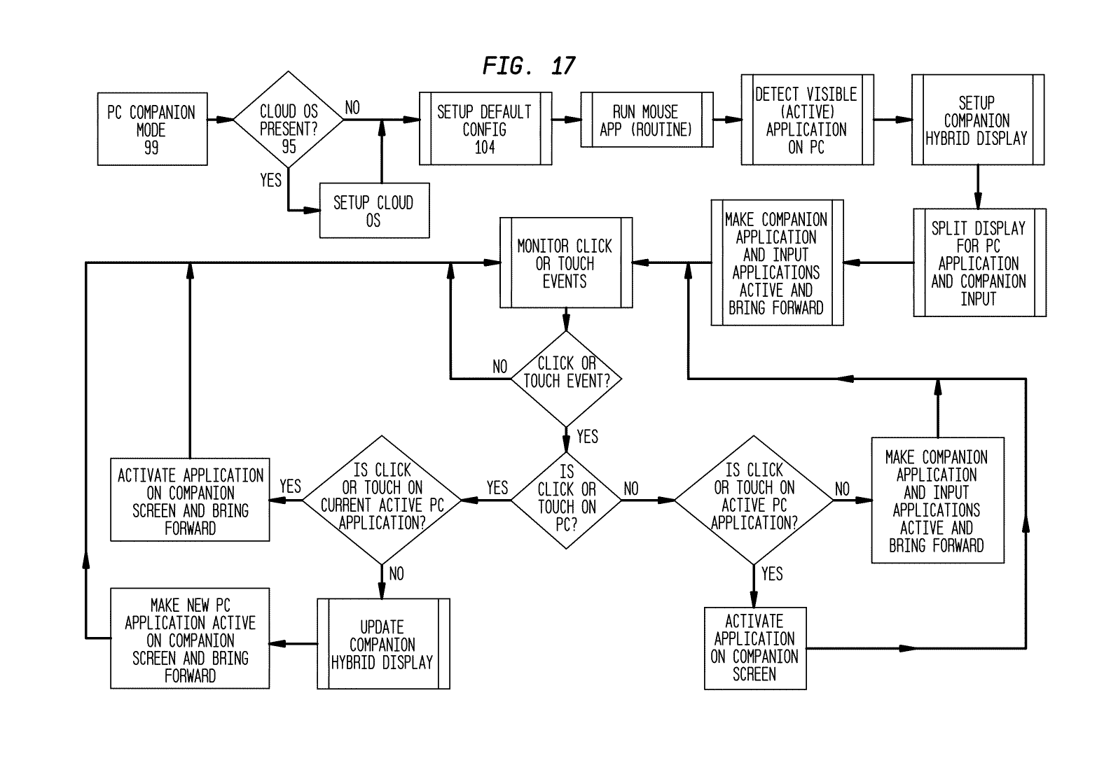

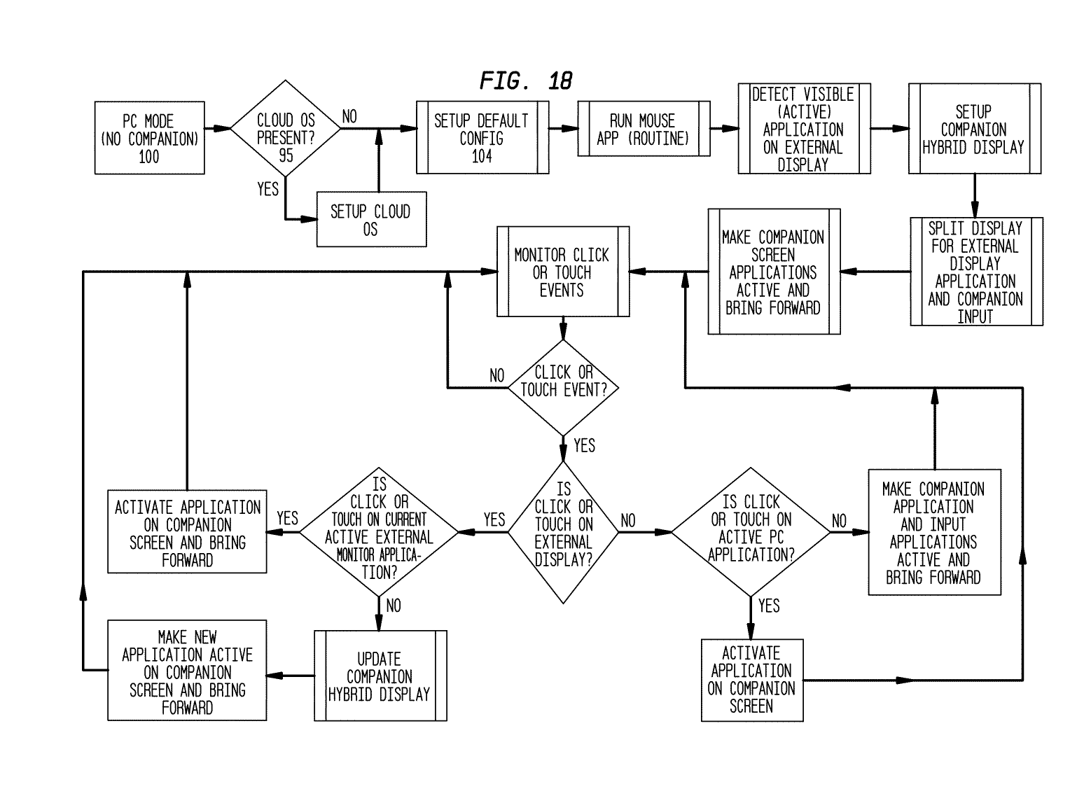

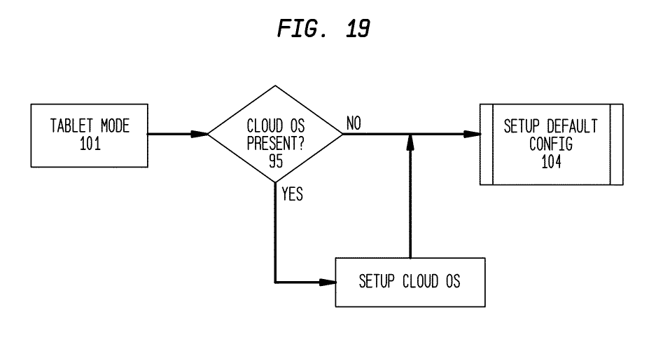

In a second mode step (98), either by independent operation of the mode module (81) or by user (2) interaction in a companion graphical user interface (3), as described below, a mode of operating the companion computer device (1) can be selected based on the modes detected including, a personal computer companion mode (99) in which the companion computer device (1) interconnects and interoperates with a personal computer (96) (as shown in the example of FIG. 17 in which the personal computer operates as a fat personal computer, thin personal computer (97), or cloud computer (95) (as shown in the example of FIG. 2)), a personal computer mode (99) in which the companion computer device (1) interconnects and interoperates only with a monitor (8) (as shown in the example of FIG. 18), or a tablet computer mode (100) in which the companion computer device (1) operates without interconnectivity to any other hardware (as shown in the example of FIG. 19). However, these examples are not intended to be exclusive of other mode routines that could be utilized as technology develops or with respect to the decision path implemented by operation of the mode module (81) in selection of a one or more modes with the first computer device (7) or the second computer device (9), a monitor (8) or in the absence of other hardware.

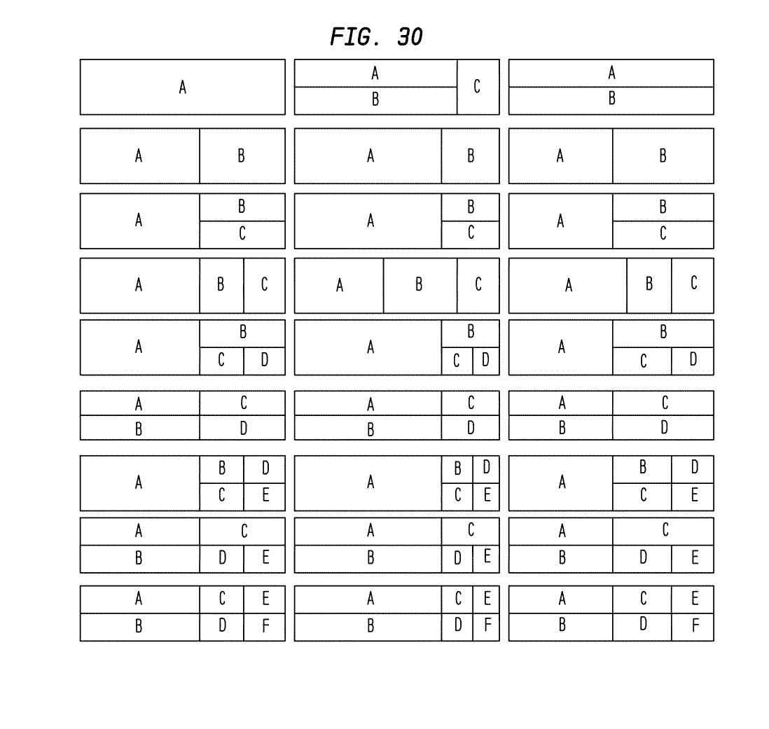

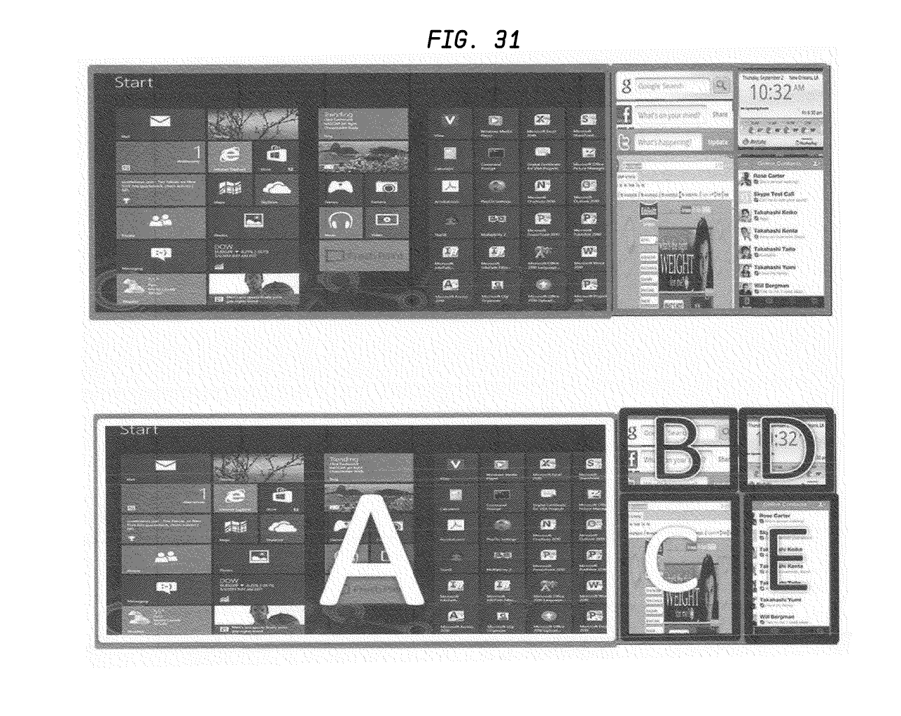

The system configuration can further include a layout configuration module (122) for the companion computer device (1). The layout module can generate a default layout configuration. Referring to FIG. 30, which shows a subset of possible screen layout configurations, the system can set one of many possible screen layouts. The screen can be configured to have many different blocks and layouts as identified by letters A, B, C, D, E and F in FIG. 30 and as many independent applications can be executed concurrently in each block or window. Referring to FIG. 31, the display is allocated to five individual blocks or windows where Windows 8 is assigned to block “A”, Search and social links assigned to block “B”, Internet Explorer to block “C”, and SKYPE to block “E”. Each of these applications and blocks are running concurrently and independently. For example the user can watch a game in one block, while using instant messaging, in another block, email in another, while working on a document in a larger block or window at the same time. The specific layouts can be selected to optimize user preferences and experience or to meet the requirements or demands of individual applications. The user can easily select from a list of predefined layouts as depicted in FIG. 30 or design their own. Applications can then be assigned to each block by user or by the system using the application assignment routine. The assignment can be done choosing each app for each block using a list or by simply pressing on the icon of an app, dragging it onto the target block and dropping it, or via predefined hot keys. The app will reside in that specific block until a new app is assigned to the block or a new layout is selected. The user can configure, name and save as many as default configuration as they like and can simply load them on demand. The location or assignment of each application can also be switched between blocks by simply dragging the app from one block to another. The two applications will simply switch locations or blocks, but continue to run without problem.

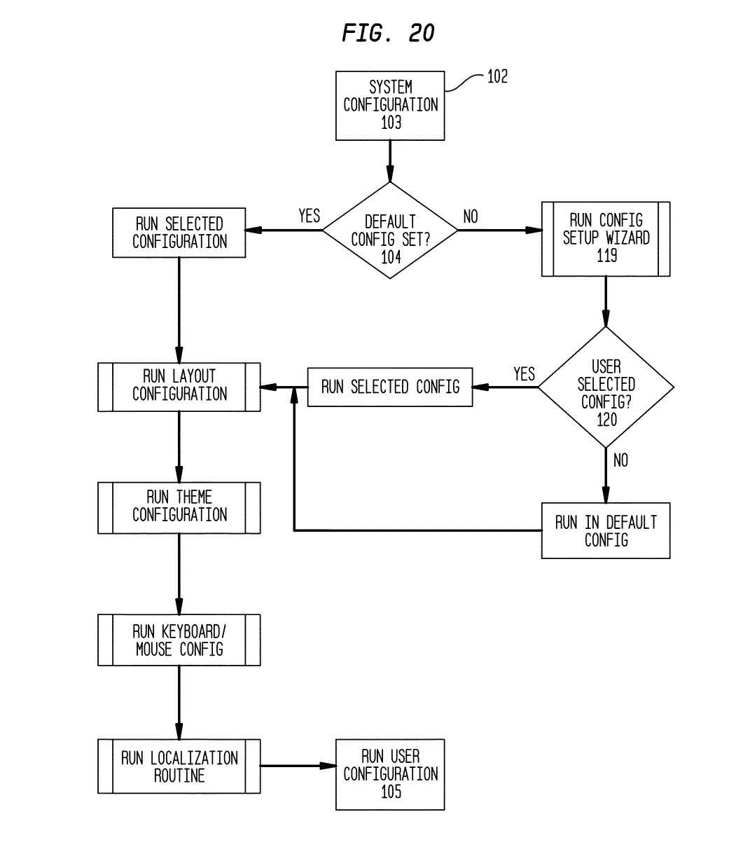

Again referring to FIGS. 10 and 11, the companion application program (16) can further include a configuration module (82) which functions in a first configuration step (102) to generate a system configuration (103) for the companion computer device (1) depending upon the connection selected by the connection module (80) and the mode selected by the mode module (81). The configuration module (82) can generate a default system configuration (104) or can by user interaction with a companion graphical user interface (3) operate a system configuration wizard (119) to generate a user selected system configuration (120) (as shown in the example of FIG. 20).

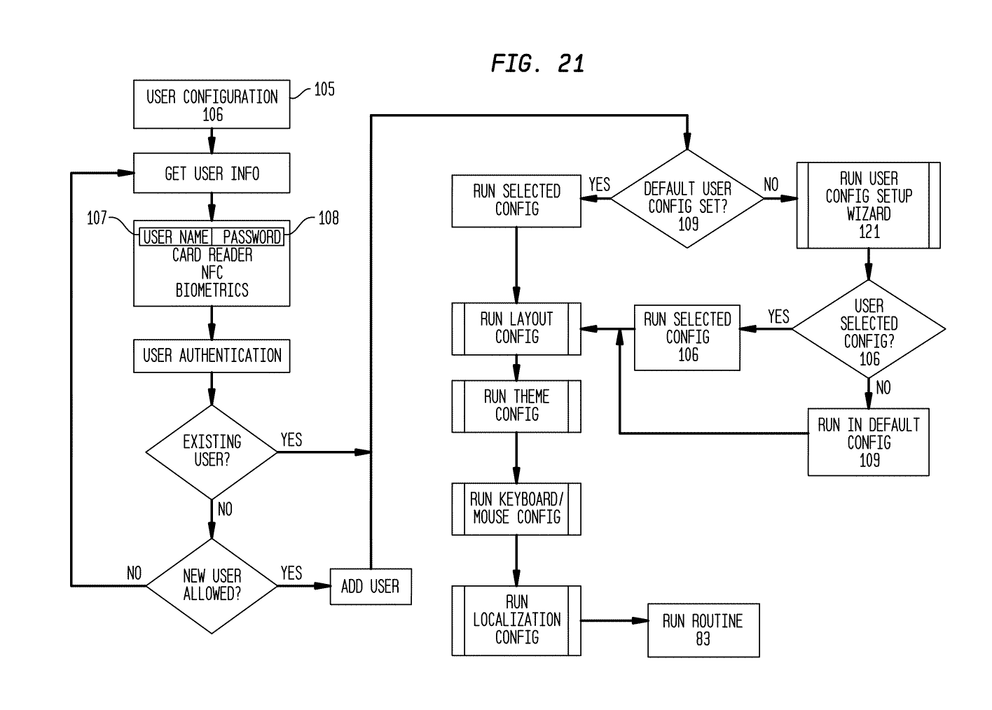

In a second configuration step (105), the configuration module (82) can generate a user configuration (106). The user (2) can access the system based on input of user identification data such as a user name (107) and a password (108) or other use identifying data such as card swipe, biometric data such as finger print, image recognition or the like. The configuration module (82) can further function to select a default user configuration (109) or by interaction of the use with a companion graphical user interface (3) the configuration module (82) can run a user configuration wizard (121) to generate user (2) selected user configuration (105) (as shown in the example of FIG. 21).

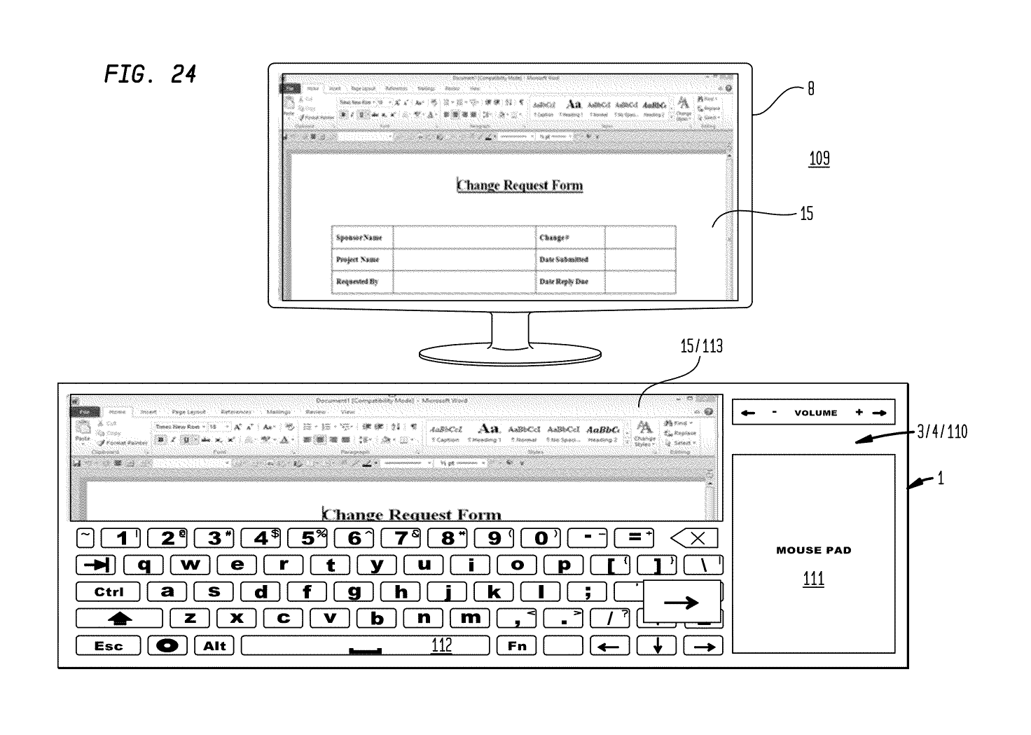

Now referring primarily to FIGS. 17, 22, and 24, which provide an illustrative example in which connection module (80) provides interconnectivity with a first computer (7) and the mode module (81) provides interoperability in the a personal computer companion mode (99) (as shown in the example of FIG. 16) and which the configuration module (82) functions to provide a first configuration (109) (also referred to as the “user default configuration”) in which the first computer (7) operates an application program (16) (for example a word processing program (40) such as WORD) to display on the monitor (8) (also referred to as “monitor 1”) the user interface (15) (also referred to as “PC Video”) corresponding to the application program (16) (as shown in the example of FIG. 24 as a user interface (15) for WORD) and the configuration module (82) further operates to detect and identify the application program (16) to correspondingly configure the companion computer device (1) to interoperate with the first computer (7) in the context of the application program (16) and to replace the first computer input devices (17) (such as a keyboard and mouse) by display of a companion graphical user interface (3) (also referred to as “CPC Video”) on the companion display surface (4) (also referred to as “monitor 2”) which includes the concurrent display of graphical input devices (110) for performing click events (5) in the application program (39) by user (2) interactive touches on the companion display surface (4). For example, in the context of a word processing application program (40) the companion graphical user interface (3) can include concurrent display of a mouse image (111) and a keyboard image (112) operable by touch interaction of the user (2) on the companion display surface (4).

The configuration module (82) can further operate to concurrently display as part of the companion graphical user interface (3), the user interface (15) for the application program (16), or a tool bar application (113) associated with the application program (39), running on the first computer (7) operable in the companion graphical user interface (3) by touch interaction of the user (2) on the companion display surface (4) (as shown in the example of FIG. 24 in which the tool bar (113) of the program application (39) is displayed). As to particular embodiments and depending upon the application program (39) running in the first computer (7) the configuration module (82) can further concurrently display in the companion graphical user interface (3) a volume control image (114) operably by user (2) touch on the companion display surface (4). In the illustrative example of the first configuration (109), as above described, the configuration module (82) can limits display of the companion graphical user interface (3) to the companion display surface (4) and does not allow display of the companion graphical user interface (3) on the first monitor (8).

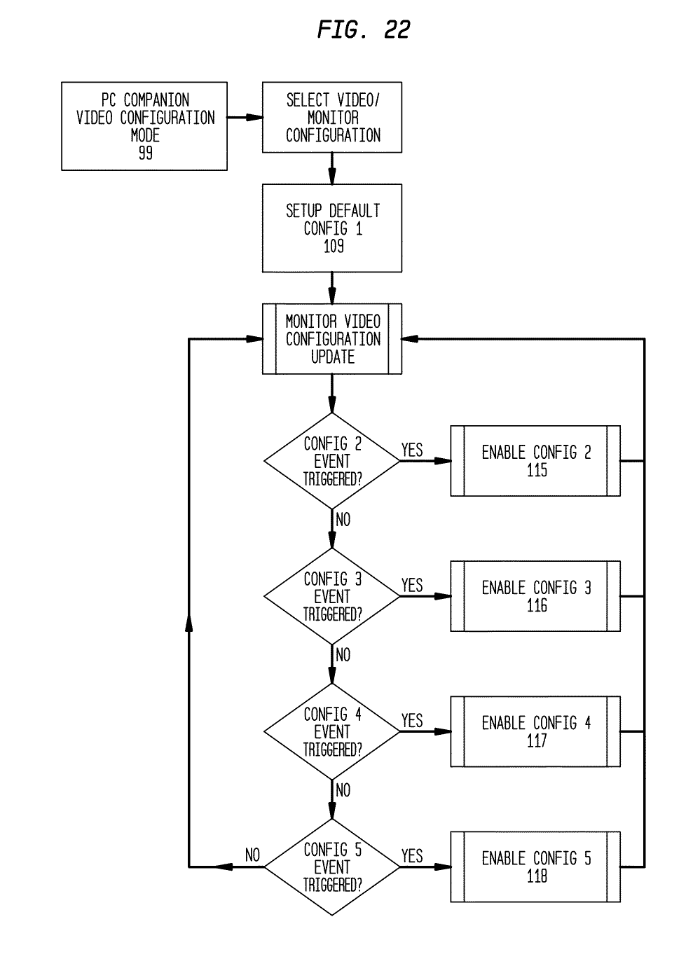

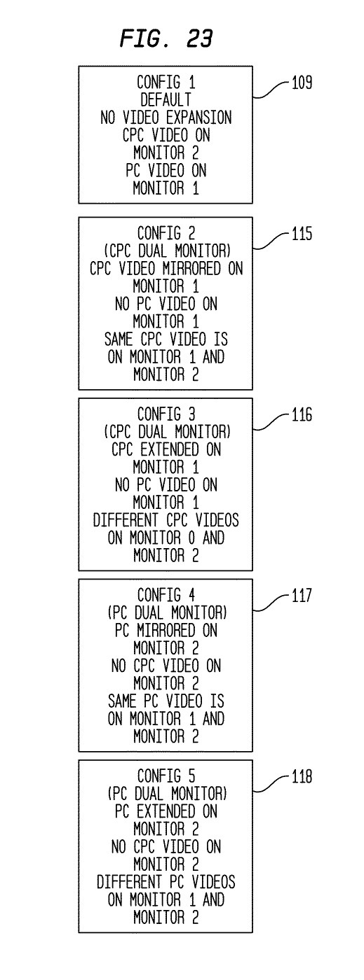

Now referring primarily to FIGS. 22 and 23, the configuration module (82) by user (2) interaction in the companion graphical user interface (3) can select or enable any one of a plurality of user configurations (105) (as shown for example in FIGS. 22 and 23 as a second configuration (115), a third configuration (116), a fourth configuration (117), and fifth configuration (118)).

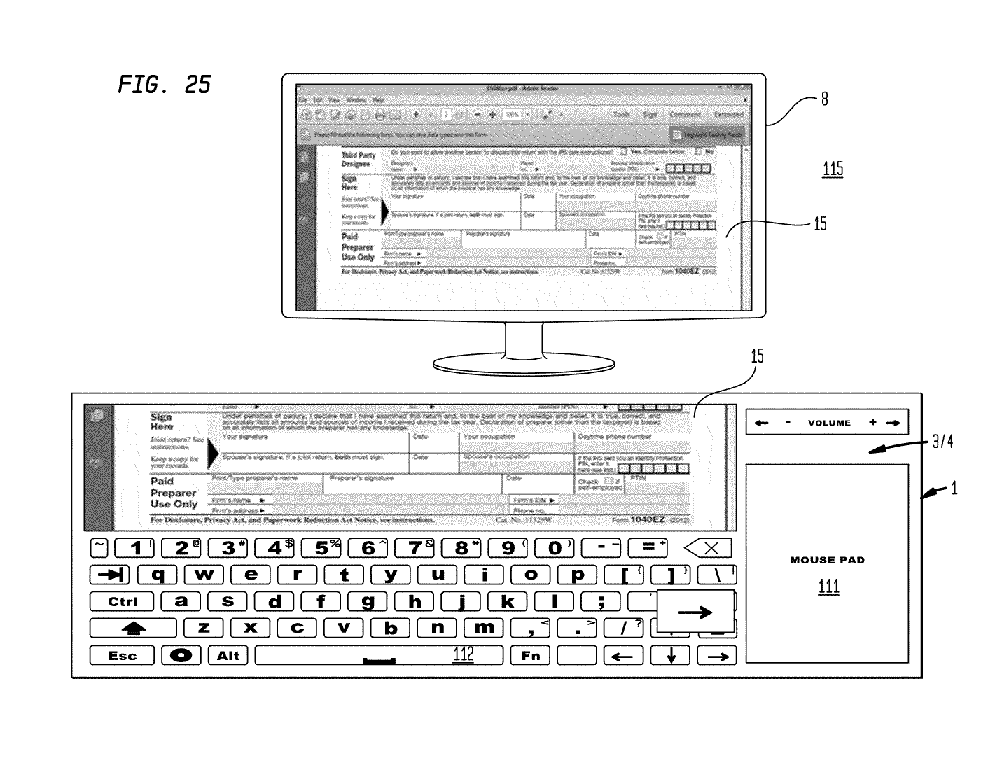

In the illustrative example of the second configuration (115) (as shown in the example of FIGS. 23 and 25), the configuration module (82) can display the companion graphic user interface (3) on both the first monitor (8) and on the companion display surface (4) (the same image displayed in both the first monitor (8) and the second monitor (4)). In the second configuration (115), the user interface (15) for the application program (39) is not displayed outside of the companion graphical user interface (3).

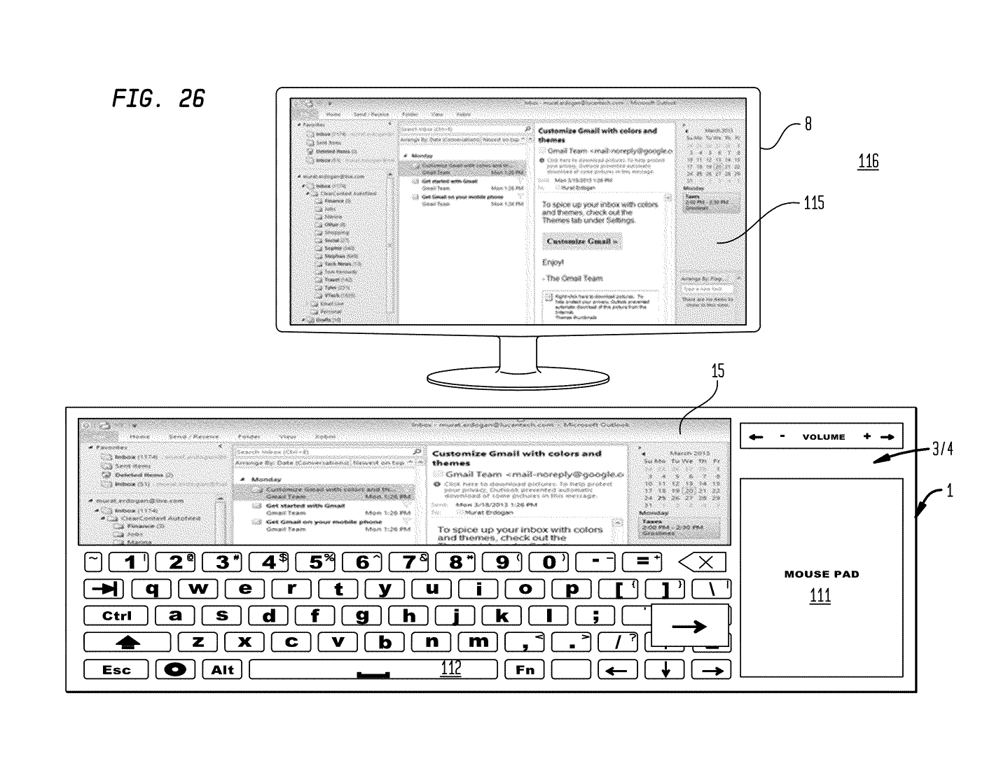

In the illustrative example of the third configuration (116) (as shown in the example of FIGS. 23 and 26), the configuration module (82) can display the companion graphic user interface (3) on both the first monitor (8) and on the companion display surface (4). In the third configuration (116), the user interface (15) for the application program (39) is not displayed outside of the companion graphic user interface (3).

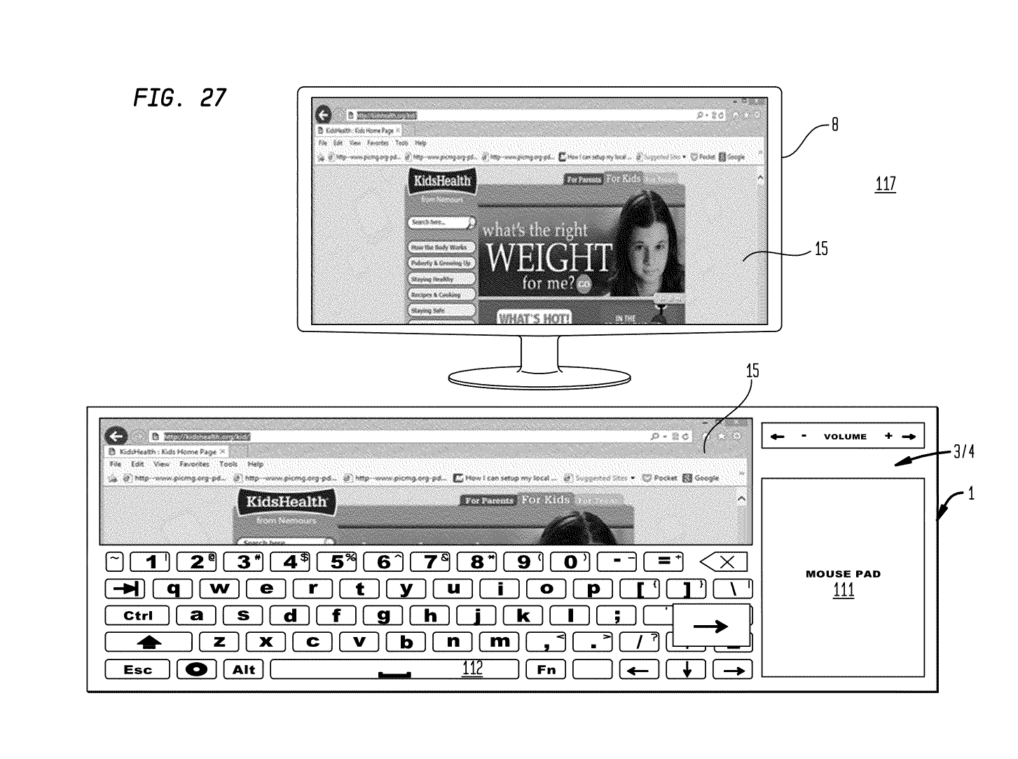

In the illustrative example of the fourth configuration (117) (as shown in the example of FIGS. 23 and 27), the configuration module (82) can display the user interface (15) for the application program (39) on both the first monitor (8) and on the companion display surface (4). In the fourth configuration (117), the companion graphical user interface (3) displays the user interface (15) for the application program.

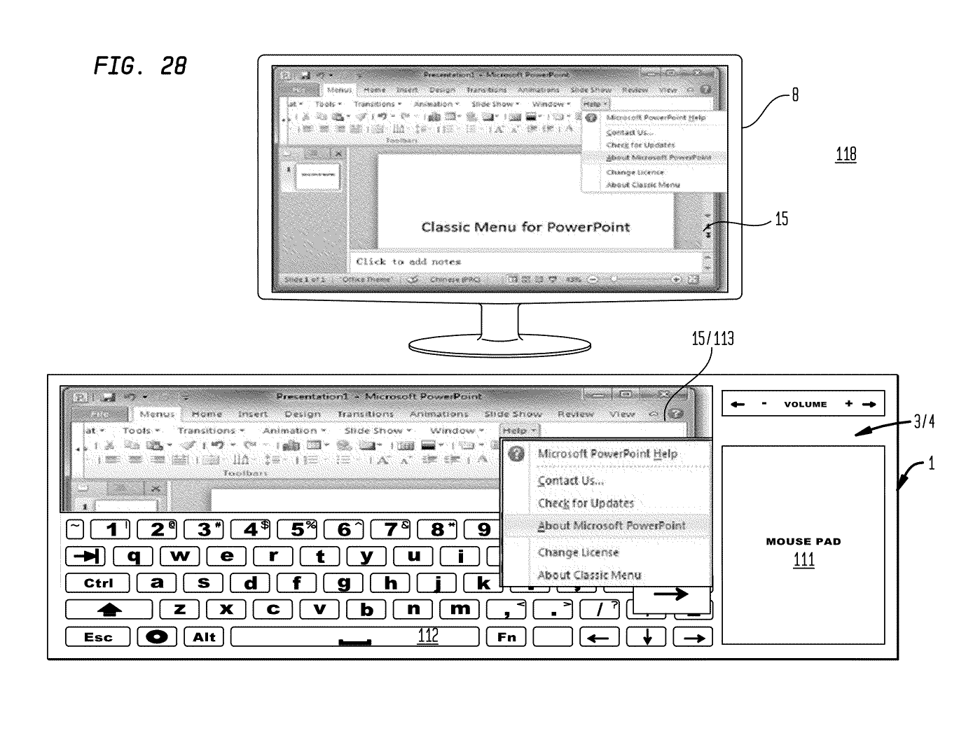

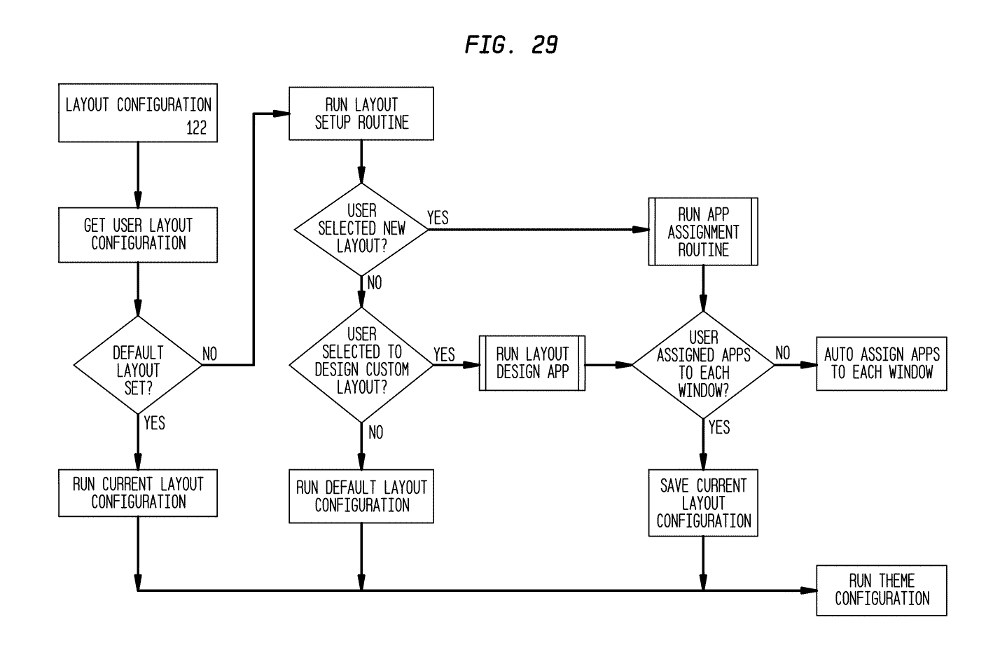

In the illustrative example of the fifth configuration (118) (as shown in the example of FIGS. 23 and 28), the configuration module (82) can display the user interface (15) for the application program (39) on an extended display surface (119) between the first monitor (7) and on the companion display surface (4). In the fifth configuration (118), the companion graphical user interface (3) displays the user interface (15) for the application program (39) on an extended work surface between the first monitor (8) and the companion device display surface (4).

Again referring to 10, the companion application program (6) can further include a run module (83) which functions to operate the companion computer device (1) based on the connection made with any of a plurality of computer systems, monitors or in the tablet mode and in the configuration selected as shown in the illustrative examples of FIGS. 16, 20, 21, 24, 25, 26, 27, and 28.

As can be easily understood from the foregoing, the basic concepts of the present invention may be embodied in a variety of ways. The invention involves numerous and varied embodiments of an interactive oral presentation display system and methods making and using an interactive display for oral presentation.

As such, the particular embodiments or elements of the invention disclosed by the description or shown in the figures or tables accompanying this application are not intended to be limiting, but rather exemplary of the numerous and varied embodiments generically encompassed by the invention or equivalents encompassed with respect to any particular element thereof. In addition, the specific description of a single embodiment or element of the invention may not explicitly describe all embodiments or elements possible; many alternatives are implicitly disclosed by the description and figures.

It should be understood that each element of an apparatus or each step of a method may be described by an apparatus term or method term. Such terms can be substituted where desired to make explicit the implicitly broad coverage to which this invention is entitled. As but one example, it should be understood that all steps of a method may be disclosed as an action, a means for taking that action, or as an element which causes that action. Similarly, each element of an apparatus may be disclosed as the physical element or the action which that physical element facilitates. As but one example, the disclosure of “a user interface” should be understood to encompass disclosure of the act of “using an interface”—whether explicitly discussed or not—and, conversely, were there effectively disclosure of the act of “using an interface”, such a disclosure should be understood to encompass disclosure of “a user interface” and even a “means for using an interface.” Such alternative terms for each element or step are to be understood to be explicitly included in the description.

In addition, as to each term used it should be understood that unless its utilization in this application is inconsistent with such interpretation, common dictionary definitions should be understood to include in the description for each term as contained in the Random House Webster's Unabridged Dictionary, second edition, each definition hereby incorporated by reference.

All numeric values herein are assumed to be modified by the term “about”, whether or not explicitly indicated. For the purposes of the present invention, ranges may be expressed as from “about” one particular value to “about” another particular value. When such a range is expressed, another embodiment includes from the one particular value to the other particular value. The recitation of numerical ranges by endpoints includes all the numeric values subsumed within that range. A numerical range of one to five includes for example the numeric values 1, 1.5, 2, 2.75, 3, 3.80, 4, 5, and so forth. It will be further understood that the endpoints of each of the ranges are significant both in relation to the other endpoint, and independently of the other endpoint. When a value is expressed as an approximation by use of the antecedent “about,” it will be understood that the particular value forms another embodiment.

Thus the applicant(s) should be understood to claim at least: i) an interactive graphical user system as herein disclosed and described, ii) the related methods disclosed and described, iii) similar, equivalent, and even implicit variations of each of these devices and methods, iv) those alternative embodiments which accomplish each of the functions shown, disclosed, or described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, ix) methods and apparatuses substantially as described hereinbefore and with reference to any of the accompanying examples, x) the various combinations and permutations of each of the previous elements disclosed.

The background section of this patent application provides a statement of the field of endeavor to which the invention pertains. This section may also incorporate or contain paraphrasing of certain United States patents, patent applications, publications, or subject matter of the claimed invention useful in relating information, problems, or concerns about the state of technology to which the invention is drawn toward. It is not intended that any United States patent, patent application, publication, statement or other information cited or incorporated herein be interpreted, construed or deemed to be admitted as prior art with respect to the invention.

The claims set forth in this international PCT patent specification are hereby incorporated by reference as part of this description of the invention, and the applicant expressly reserves the right to use all of or a portion of such incorporated content of such claims as additional description to support any of or all of the claims or any element or component thereof, and the applicant further expressly reserves the right to move any portion of or all of the incorporated content of such claims or any element or component thereof from the description into the claims or vice-versa as necessary to define the matter for which protection is sought by this application or by any subsequent application or continuation, division, or continuation-in-part application thereof, or to obtain any benefit of, reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon. The claims set forth in this specification, if any, are further intended to describe the metes and bounds of a limited number of the preferred embodiments of the invention and are not to be construed as the broadest embodiment of the invention or a complete listing of embodiments of the invention that may be claimed. The applicant does not waive any right to develop further claims based upon the description set forth above as a part of any continuation, division, or continuation-in-part, or similar application.

What is claimed is:

1. A companion computer device having touch screen which provides an interactive graphical user interface interoperable with each of a plurality of computer systems, said computer device comprising: a main enclosure for housing plurality of computer components; circuit boards containing major external connectors and hardware such as power connector, battery, Wireless radio Antennas, USB connectors, HDMI, the LCD and other common features, an opening adapted to receive at least one accessory CPU Card that includes all major components such as the microprocessor, RAM, Flash Memory, all critical chips, SD card and SIMM Card Connectors and other critical components being electrically connectable to the enclosure circuit boards by means of connectors and cables; Connectable meaning electrically connecting at least one of the said CPU Card to said circuit boards containing common feature components, one or more programs, wherein one or more programs are stored in memory and configured to be executed by one or more microprocessors, the one and more programs including: instructions for detecting the connection type between the companion device and the plurality of computer devices; instructions for detecting operation mode as an input or companion device attached to a plurality of computer systems such as a laptop, desktop, phone, a tablet or simply a monitor; a standalone tablet, a thin client tablet, a computer attached to a monitor or a thin client attached to a monitor; instructions to divide the screen display in tiles to allow for concurrent execution of multiple programs or instructions in parallel; instructions to allow for custom layout configuration of the said tiled or divided screen layouts; instructions to share display of the companion computer device with a plurality of computer devices and to display the screen of the plurality of the computing devices on the touch screen display of the companion computer device, hence allowing for direct interaction with documents, and applications of the plurality of devices;

2. The computing device of claim 1, when used as a companion PC, replacing KB and Mouse, provides input functions required to interact with plurality of devices an allows for pen input, touch interaction, keyboard input, via simulated keyboards on the touch screen and mouse input.

3. The computing device of claim 1, when used as a companion PC, replacing KB, provides simulated keyboard predefined and custom layouts, in all languages and sizes.

4. The computing device of claim 1, when used as a companion PC, detects the active application running on the plurality of computer systems and automatically configures the screen of the companion computer device based on the user preferences, predefined or built in layout configuration or the configuration file provided by the running active application.

5. The computing device of claim 1, the user removable Central Processing Unit (CPU) Card that includes all major components such as the microprocessor, RAM, Flash Memory, all critical chips, SD card and SIMM Card Connectors and other critical components is designed to be sharable between different enclosure sizes, hence allowing for easy transportation between multiple systems.
